(19) United States
(12) Patent Application Publication
(10) Pub. No.: US 2026/0324416 A1
(43) Pub. Date: Oct. 15, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Tengo ORII, Matsumoto-city (JP)

(73) Assignee: FUJI ELECTRIC CO., LTD., Kawasaki-shi (JP)

(21) Appl. No.: 19/463,666

(22) Filed: Jan. 29, 2026

(30) Foreign Application Priority Data
Mar. 13, 2025 (JP) 2025-040603

(51) Int. Cl. H10W 40/22; H10W 40/00; H10W 40/47

(52) U.S. Cl. CPC H10W 40/22; H10W 40/03; H10W 40/47

(57) ABSTRACT

A semiconductor device, including: an insulating circuit board having a front surface and a rear surface; a semiconductor element mounted on the front surface of the insulating circuit board; a heat dissipating base plate that is rectangular in shape, and that has: an upper surface to which the rear surface of the insulating circuit board is bonded; a lower surface that is opposite the upper surface; two first side surfaces that are opposite to each other, and each extend in a first direction; and two second side surfaces that are opposite to each other, and each extend in a second direction perpendicular to the first direction. The heat dissipating base plate has four recesses formed respectively in the two first side surfaces and the two second side surfaces.

### CROSS-REFERENCE TO RELATED APPLICATION(S)

This application is based upon and claims the benefit of priority of the prior Japanese Patent Application No. 2025-040603, filed on Mar. 13, 2025, the entire contents of which are incorporated herein by reference.

### BACKGROUND OF THE INVENTION

### 1. Field of the Invention

The embodiment discussed herein relates to a semiconductor device and a method of manufacturing a semiconductor device.

### 2. Background of the Related Art

In the field of semiconductor devices that include a metal plate for dissipating heat, a semiconductor device in which at least one hole for suppressing the conduction of heat is provided in a side surface of the metal plate and a semiconductor device in which channels for alleviating thermal stress are provided in side surfaces of the metal plate have been proposed (see, for example, Japanese Patent No. 7471458 and Japanese Laid-open Patent Publication No. 2012-169319). In addition, a semiconductor device in which a channel for preventing separation from a chip is provided in the side surface of a heat dissipating plate provided on the chip, and a semiconductor device in which a longitudinal channel for holding resin before curing is provided in an upper surface of a heat dissipating member have also been proposed (see, for example, International Publication Pamphlet No. WO 2023/153334 and Japanese Laid-open Patent Publication No. 2023-127609).

### SUMMARY OF THE INVENTION

According to an aspect of the present disclosure, there is provided a semiconductor device, including: an insulating circuit board having a front surface and a rear surface; a semiconductor element mounted on the front surface of the insulating circuit board; and a heat dissipating base plate that is rectangular in shape, and that has: an upper surface to which the rear surface of the insulating circuit board is bonded, a lower surface that is opposite the upper surface, two first side surfaces that are opposite to each other, and each extend in a first direction, and two second side surfaces that are opposite to each other, and each extend in a second direction perpendicular to the first direction, wherein the heat dissipating base plate has four recesses formed respectively in the two first side surfaces and the two second side surfaces.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1A is a top view of one example of a semiconductor device, and FIG. 1B is a cross-sectional view taken along a line I-I in FIG. 1A;

FIG. 2 is a cross-sectional view taken along a line II-II;

FIG. 3 is a perspective view of a heat dissipating base plate;

FIG. 4 is a plan view depicting a high-density region formed in the heat dissipating base plate;

FIG. 5A is a top view depicting an example connection of a cooler, and FIG. 5B is a cross-sectional view taken along a line V-V in FIG. 5A;

FIG. 6 depicts an example of liquid compound being pressed out when a heat dissipating base plate with no recess is used;

FIGS. 7A and 7B are diagrams useful in explaining differences in function due to differences in the shape of a recess;

FIG. 8 is a perspective view depicting a modification to the heat dissipating base plate;

FIGS. 9A and 9B are diagrams depicting examples of cracks generated in cases where an end of a recess is rectangular or is pointed with an acute angle in shape;

FIG. 10 depicts a modification to the formation position of the recess; and

FIG. 11 is a diagram illustrating the flow of one example of a manufacturing process of a semiconductor device.

### DETAILED DESCRIPTION OF THE INVENTION

Hereinafter an embodiment will be described with reference to the drawings.

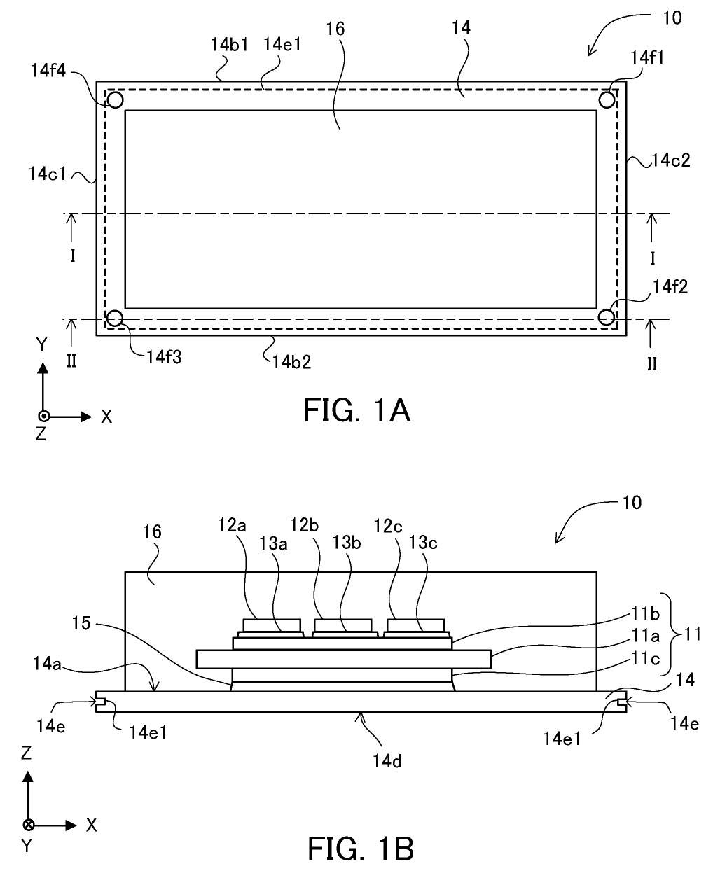

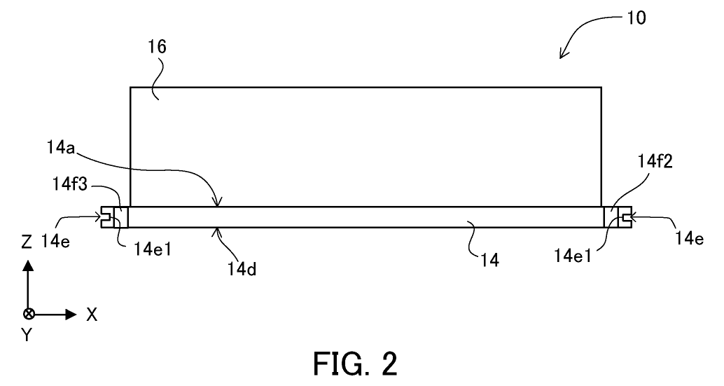

Note that in the following description, the expressions “front surface” and “upper surface” represent an X-Y plane that faces upward (that is, in the +Z direction) for a semiconductor device 10 depicted in FIGS. 1A and 1B, 2, and the like. In the same way, the expression “above” indicates an upward direction (the +Z direction) for the semiconductor device 10 in FIGS. 1A, 1B, and 2. The expressions “rear surface” and “lower surface” represent an X-Y plane that faces downward (in the −Z direction) for the semiconductor device 10 in FIGS. 1A, 1B, 2, and the like. In the same way, the expression “below” indicates a downward direction (the −Z direction) for the semiconductor device 10 in FIGS. 1A, 1B, and 2. The same directions are also used as needed in other drawings. The expressions “front surface”, “upper surface”, “above”, “rear surface”, “lower surface”, and “below” are merely convenient expressions for specifying relative positional relationships, and do not limit the technical scope of the present disclosure. As one example, the expressions “above” and “below” do not necessarily refer to the vertical direction with respect to the ground. That is, the “above” and “below” directions are not limited to the direction of gravity.

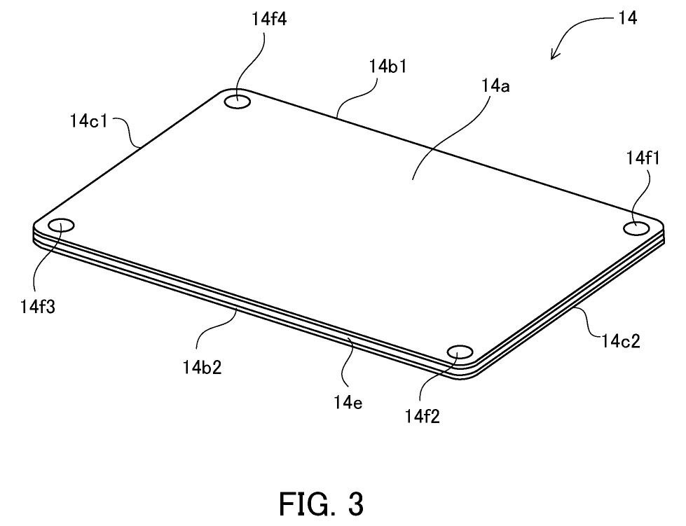

FIG. 1A is a top view of one example of a semiconductor device, and FIG. 1B is a cross-sectional view taken along a line I-I in FIG. 1A. FIG. 2 is a cross-sectional view taken along a line II-II. FIG. 3 is a perspective view of a heat dissipating base plate.

As one example, the semiconductor device 10 is mounted on a power converter apparatus, such as an inverter or a power conditioner. The semiconductor device 10 includes an insulating circuit board 11 on whose front surface semiconductor elements 12a to 12c are mounted, a heat dissipating base plate 14, and a housing 16.

As depicted in FIG. 1B, the insulating circuit board 11 includes an insulating board 11a, a metal plate 11b provided on a front surface of the insulating board 11a, and a metal plate 11c provided on a rear surface of the insulating board 11a. A bonding material such as solder may be used to bond the metal plates 11b and 11c to the insulating board 11a.

The insulating board 11a is rectangular in shape in plan view. Corner portions of the insulating board 11a may be chamfered into rounded or beveled shapes. As one example, the insulating board 11a may be an insulating board that includes a ceramic as a main component. This ceramic is made of a material containing aluminum oxide, aluminum nitride, or silicon nitride as a main component, for example.

The metal plate 11b is made of a metal with superior electrical conductivity. Example metals include copper, aluminum, or an alloy containing at least one of these metals. The metal plate 11b may be divided into a plurality of conductive patterns.

The metal plate 11c is rectangular in shape in plan view. Corner portions may be chamfered into rounded or beveled shapes. The metal plate 11b has a metal with superior thermal conductivity as a main component. Example metals include copper, aluminum, or an alloy containing at least one of these metals.

As examples, a direct copper bonding (DCB) substrate, an active metal brazed (AMB) substrate, or the like may be used as the insulating circuit board 11.

The semiconductor elements 12a to 12c are mounted on the main surface of the insulating circuit board 11. The main surface of the insulating circuit board 11 is the front surface (upper surface) of the metal plate 11b. The semiconductor elements 12a to 12c are bonded to the front surface of the metal plate 11b by bonding materials 13a to 13c, such as solder.

The semiconductor elements 12a to 12c are switching elements made of silicon, silicon carbide, or gallium nitride. As examples, such switching elements are insulated gate bipolar transistors (IGBTs) or power metal-oxide-semiconductor field-effect transistors (MOSFETs). The semiconductor elements 12a to 12c may also be reverse-conducting-IGBTs (RC-IGBTs). An RC-IGBT has both the functions of an IGBT and a freewheeling diode (FWD). The switching elements may be power MOSFETs made of silicon carbide. In this case, the body diode of the power MOSFET may have the same function as the FWD of an RC-IGBT.

Although not illustrated, main electrodes and control electrodes are provided on the front surfaces of the semiconductor elements 12a to 12c. When the semiconductor elements 12a to 12c are IGBTs, these main electrodes are emitter electrodes. When the semiconductor elements 12a to 12c are power MOSFETs, these main electrodes are source electrodes. The main electrodes on the front surfaces are electrically connected via connection members to external terminals (as examples, positive terminals, negative terminals, or output terminals), not illustrated. The control electrodes are gate electrodes of the semiconductor elements 12a to 12c. The control electrodes are electrically connected via connection members to control terminals (not illustrated) or the like.

Although not illustrated, main electrodes are also provided on the rear surfaces of the semiconductor elements 12a to 12c. When the semiconductor elements 12a to 12c are IGBTs, the main electrodes on the rear surfaces are collector electrodes. When the semiconductor elements 12a to 12c are power MOSFETs, the main electrodes on the rear surfaces are drain electrodes. The main electrode on the rear surface of each of the semiconductor elements 12a to 12c is electrically connected to an external terminal or a main electrode on the rear surface of another semiconductor element. Although not illustrated, one end of the external terminal, the control terminal, or the like may be exposed at the upper surface of the housing 16, for example, for the purpose of being externally connected.

Note that the number of semiconductor elements is not limited to the embodiment described above. A number of semiconductor elements are provided in keeping with the specification and the like of the semiconductor device 10. Other semiconductor elements, such as diode elements, may also be mounted on the insulating circuit board 11.

The heat dissipating base plate 14 may be rectangular in shape and include an upper surface 14a, two opposing first side surfaces 14b1 and 14b2 connected to the upper surface 14a, two opposing second side surfaces 14c1 and 14c2 which are connected to the two first side surfaces 14b1 and 14b2 and extend in a direction perpendicular to the direction in which the first side surfaces 14b1 and 14b2 extend, and a lower surface 14d that is opposite the upper surface 14a and is connected to the first side surfaces 14b1 and 14b2 and the second side surfaces 14c1 and 14c2. The rear surface of the insulating circuit board 11 is bonded to the upper surface 14a of the heat dissipating base plate 14 by a bonding material 15, such as solder.

The two first side surfaces 14b1 and 14b2 and the two second side surfaces 14c1 and 14c2 are provided with a recess 14e whose bottom 14e1 is located inside the heat dissipating base plate 14. In FIG. 1A, the bottom 14e1 of the recess 14e is indicated by a dotted line.

As depicted in FIGS. 1A and 3, the recess 14e is provided continuously without interruption in the two first side surfaces 14b1 and 14b2 and the two second side surfaces 14c1 and 14c2. As depicted in FIGS. 1B and 2, the recess 14e is located between the upper surface 14a and the lower surface 14d of the heat dissipating base plate 14, and is provided near the center in the height direction of the first side surfaces 14b1 and 14b2 and the second side surfaces 14c1 and 14c2.

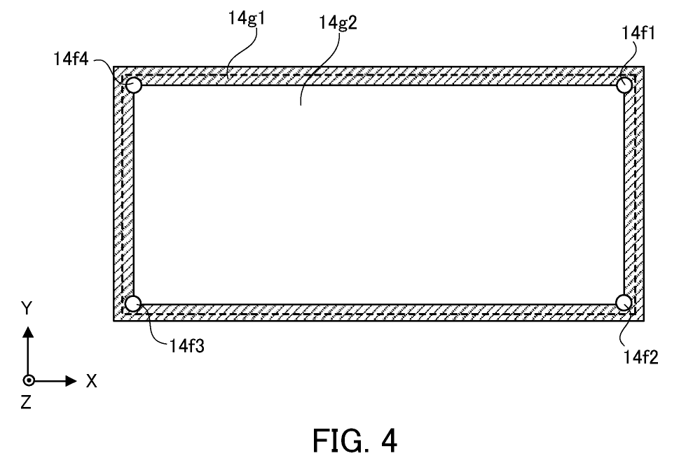

The recess 14e is formed by press machining. Note that when the recess 14e is formed too deep, there will be deterioration in thermal conductivity. Also, when the recess 14e is formed too deep, the thickness of the heat dissipating base plate 14 will not be uniform and molding defects may occur. Conversely, when the recess 14e is formed too shallow, a high-density region (see FIG. 4), described later, in an edge portion of the heat dissipating base plate 14 including the recess 14e is too small. With consideration to these factors, the recess 14e is preferably located outside the edges of the insulating circuit board 11 (that is, the ends in the X direction of the insulating circuit board 11). Although the width of the recess 14e in the thickness direction (Z direction) of the heat dissipating base plate 14 is constant up to the bottom 14e1, this is not a limitation for the present disclosure. As another example, the width of the recess 14e in the thickness direction (Z direction) of the heat dissipating base plate 14 may narrow toward the bottom 14e1.

The heat dissipating base plate 14 also includes through-holes 14f1 to 14f4 that pass through from the upper surface 14a to the lower surface 14d at four corners in plan view. The through-holes 14f1 to 14f4 are holes into which fastening screws used to fix the heat dissipating base plate 14 to a cooler, described later, are inserted.

As depicted in FIGS. 1A and 2, the bottom 14e1 of the recess 14e is located further to the outside of the heat dissipating base plate 14 than the through-holes 14f1 to 14f4. That is, the bottom 14e1 of the recess 14e is provided between the through-holes 14f1 to 14f4 and the two first side surfaces 14b1 and 14b2 and the two second side surfaces 14c1 and 14c2. This means that it is possible to prevent the recess 14e from obstructing the insertion of the fastening screws into the through-holes 14f1 to 14f4.

A metal that has high thermal conductivity, is relatively easy to process, and is relatively inexpensive is used as the material of the heat dissipating base plate 14. As examples, metal including copper and aluminum, or an alloy containing at least one of these metals may be used.

The housing 16 is formed on the upper surface 14a of the heat dissipating base plate 14, encapsulates the insulating circuit board 11 and the semiconductor elements 12a to 12c, and also encapsulates parts of the external terminals and the control terminals (not illustrated). The housing 16 may be molded by resin molding, such as transfer molding. Note that the housing 16 includes a resin case and an encapsulating resin that fills the inside of the resin case.

FIG. 4 is a plan view depicting a high-density region formed in the heat dissipating base plate. As described above, since the recess 14e is formed by press machining, the edge portion of the heat dissipating base plate 14 including the recess 14e includes a high-density region 14g1 with a higher density than a remaining region 14g2 of the heat dissipating base plate 14.

The high density region 14g1 is a region that is affected by press machining and the region 14g2 is a region that is unaffected by press machining. Since the density of the high density region 14g1 increases due to the effect of the press machining, the high density region 14g1 has higher bending rigidity than the region 14g2 and is a rigid region.

In the semiconductor device 10 described above, heat generated from the semiconductor elements 12a to 12c is dissipated to the outside via the insulating circuit board 11, the bonding material 15, and also the heat dissipating base plate 14, thereby cooling the semiconductor device 10.

When heat generated from the semiconductor elements 12a to 12c is transmitted to the insulating circuit board 11 and the heat dissipating base plate 14, to efficiently dissipate the heat to the outside, the semiconductor device 10 may further include a cooler as described below.

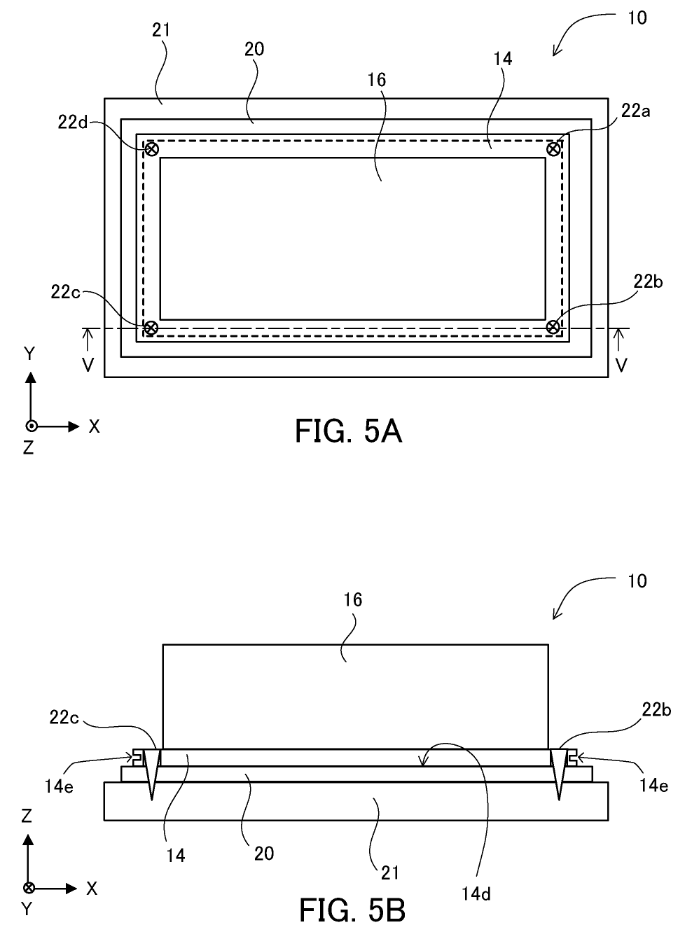

FIG. 5A is a top view depicting an example connection of a cooler, and FIG. 5B is a cross-sectional view taken along a line V-V in FIG. 5A. As depicted in FIGS. 5A and 5B, the semiconductor device 10 further includes a cooler 21 connected to the lower surface 14d of the heat dissipating base plate 14 via the liquid compound 20.

The liquid compound 20 is also referred to as "thermal grease" and is used to fill minute irregularities in a bonding surface between the lower surface 14d of the heat dissipating base plate 14 and the cooler, thereby improving the thermal conductivity. As one example, silicone resin or the like is used as the liquid compound 20. Particles (or "thermally conductive filler") of a metal or metal oxide with high thermal conductivity, such as copper (Cu), silver (Ag), or alumina (Al₂O₃), may be mixed into the liquid compound 20. As the liquid compound 20, a material with suitable viscosity and performance is selected as appropriate according to the application.

Cooling fins made of aluminum, copper, or the like are used as the cooler 21. The cooler 21 is fixed to the heat dissipating base plate 14 by fastening screws 22a to 22d that have been inserted into the through-holes 14f1 to 14f4 provided in the heat dissipating base plate 14.

During normal use of the semiconductor device 10, the semiconductor device 10 is exposed to temperature cycles with the mounted semiconductor elements 12a to 12c as heat sources. Due to these temperature cycles, each member that constructs the semiconductor device 10 repeatedly expands and contracts due to heat in keeping with the respective thermal expansion coefficients of the members, and constantly exhibits warping and deformation-type behavior.

As a comparative example, problems that occur when a heat dissipating base plate with no recess 14e is used will be described.

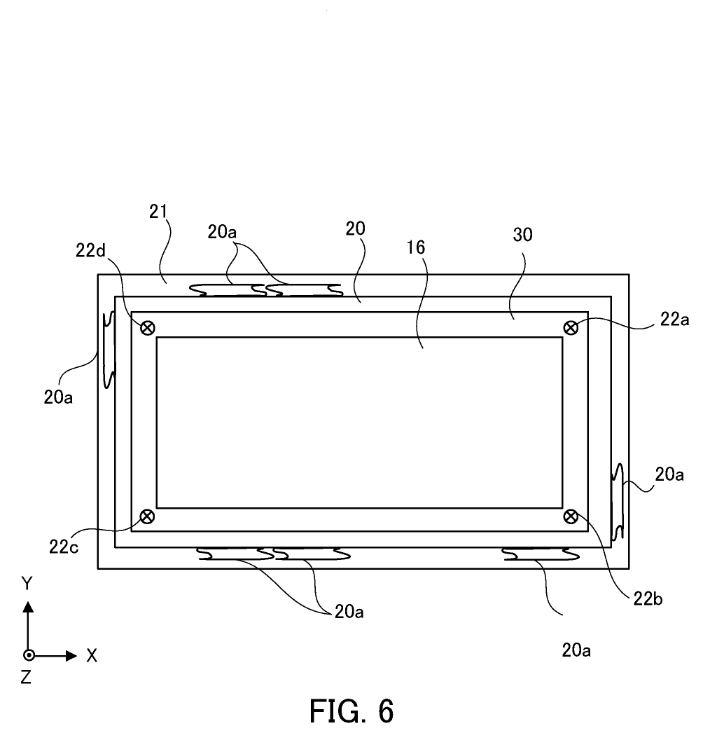

FIG. 6 depicts an example of liquid compound being pressed out when a heat dissipating base plate with no recess is used. In FIG. 6, elements that are the same as those depicted in FIGS. 5A and 5B have been assigned the same reference numerals.

When a heat dissipating base plate 30 with no recess 14e is used, the liquid compound 20 applied between the heat dissipating base plate 30 and the surface of the cooler 21 is pressed out from the joint due to thermal expansion and warping of the respective members, such as the heat dissipating base plate 30 and the insulating circuit board 11. FIG. 6 depicts pressed-out portions 20a, which are parts of the extruded liquid compound 20 that have been pressed out.

When the liquid compound 20 has been pressed out in this way, the conduction of heat is impaired and there is deterioration in heat dissipation. As a result, the heat generated from the semiconductor elements 12a to 12c is not sufficiently dissipated, and there is the risk of this leading to thermal breakdown of the semiconductor elements 12a to 12c.

One effective countermeasure for suppressing warping-type behavior is to change the materials. However, since the materials of the respective members are selected so as to reduce the differences in thermal expansion coefficients between members as much as possible and thereby minimize the strain between the materials, this is not an optimal solution.

In contrast to the semiconductor device including the heat dissipating base plate 30 described here, the semiconductor device 10 according to the present embodiment includes the heat dissipating base plate 14 provided with the recess 14e. As depicted in FIG. 4, the edge portion of the heat dissipating base plate 14 that includes the recess 14e is the high-density region 14g1 that has a higher density than the other region 14g2 of the heat dissipating base plate 14, and therefore has higher bending rigidity than the region 14g2, making it a rigid region. This results in the heat dissipating base plate 14 of the semiconductor device 10 having higher bending rigidity as a whole than the heat dissipating base plate 30. Since the bending rigidity is improved, warping-type behavior is suppressed and the amount of warping deformation is reduced, which reduces the pressing out of the liquid compound 20. As a result, it is possible to solve the problem of thermal breakdown described above. In addition, by providing the recess 14e in the heat dissipating base plate 14, it is possible to reduce the pressing out of the liquid compound 20 without changing the materials used for the respective members.

By applying such a semiconductor device 10 to a power converter apparatus, it is possible to cope with future increases in current density, in a background where the trend is for further miniaturization of power converter apparatuses.

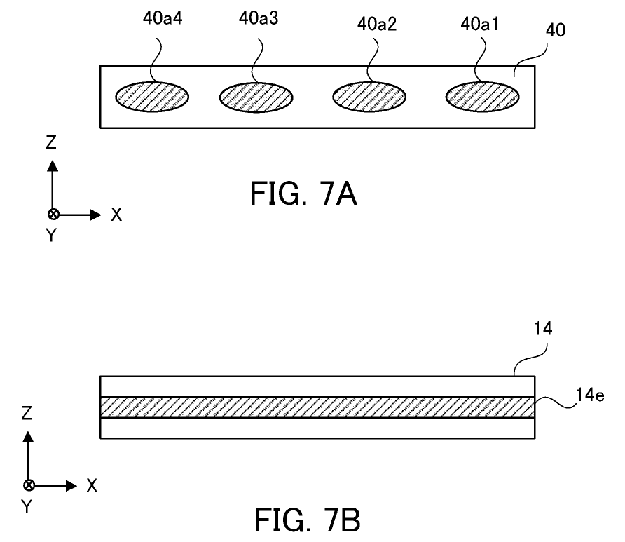

FIGS. 7A and 7B are diagrams useful in explaining differences in function due to differences in the shape of a recess. FIG. 7A depicts a heat dissipating base plate 40 in which a plurality of recesses 40a1 to 40a4, which are elliptical in shape in a side view, have been formed in a side surface by press machining. FIG. 7B depicts the heat dissipating base plate 14 according to the present embodiment, which includes the recess 14e that is provided continuously without interruption on the side surfaces (the first side surfaces 14b1 and 14b2 and the two second side surfaces 14c1 and 14c2 in FIGS. 1A and 1B).

When the recesses 40a1 to 40a4 with the shape depicted in FIG. 7A are used, when looking in the Z direction, due to the density-increasing effect, there is a mixture of locations whose strength has increased and locations where this has not happened. In this case, the improvement in bending rigidity is limited.

On the other hand, when the recess 14e with the shape depicted in FIG. 7B is used, when looking in the Z direction, the structural strength is uniform at every location, which improves the bending rigidity as a whole. In particular, in order to prevent the liquid compound 20 from being pressed out from the joint without impairing the wettability and spreadability of the liquid compound 20, it is important to construct the heat dissipating base plate 14 with a distribution of strength such that the outer side in plan view is rigid and the inner side is flexible. When the recess 14e with the shape depicted in FIG. 7B is used, the structural strength is uniform at any location, which makes it possible to improve the bending rigidity as a whole. This makes it possible to more reliably reduce the pressing out of the liquid compound 20.

As depicted in FIG. 4, the heat dissipating base plate 14 according to the present embodiment is provided with the high density region 14g1 at the edge portion which includes the recess 14e, which produces a strength distribution where the outer side in plan view is rigid and the inner side is flexible. This means that it is possible to prevent the liquid compound 20 from being pressed out from the joint without impairing the wettability and spreadability of the liquid compound 20. The recess 14e is located between the upper surface 14a and the lower surface 14d of the heat dissipating base plate 14, and is provided near the center in the height direction of the first side surfaces 14b1 and 14b2 and the second side surfaces 14c1 and 14c2. Accordingly, it is possible to make the strength of the high density region 14g1 uniform in the thickness direction (the Y direction) of the heat dissipating base plate 14, which makes it possible to improve the bending rigidity more reliably.

### Modifications

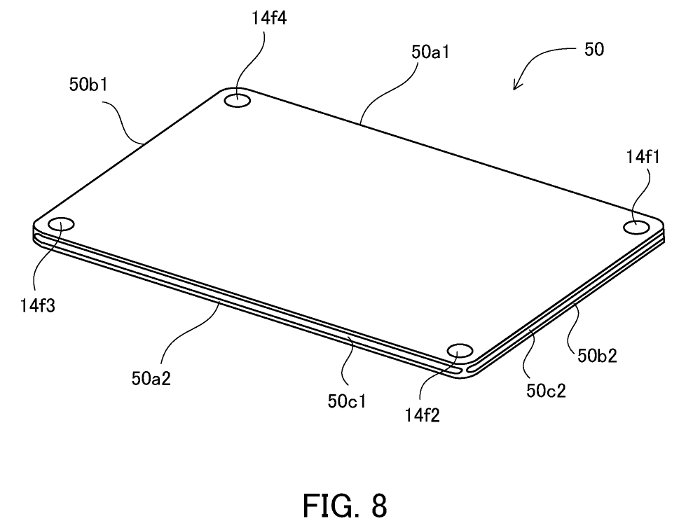

FIG. 8 is a perspective view depicting a modification to the heat dissipating base plate. In FIG. 8, elements that are the same as in the heat dissipating base plate 14 depicted in FIG. 3 and the like have been assigned the same reference numerals.

As with the heat dissipating base plate 14 depicted in FIG. 3 and the like, the heat dissipating base plate 50 according to this modification includes two opposing first side surfaces 50a1 and 50a2, and two opposing second side surfaces 50b1 and 50b2 that extend in a direction that is perpendicular to the direction in which the first side surfaces 50a1 and 50a2 extend.

However, in the heat dissipating base plate 50, recesses are separately provided in the two first side surfaces 50a1 and 50a2 and the two second side surfaces 50b1 and 50b2. The perspective view in FIG. 8 depicts a recess 50c1 provided in the first side surface 50a2 and a recess 50c2 provided in the second side surface 50b2.

Both ends of the recesses 50c1 provided so as to extend in the direction in which the first side surface 50a2 extends are rounded. That is, both ends are chamfered into rounded shapes. Both ends of the recess 50c2 provided so as to extend in the perpendicular direction (that is, the direction in which the second side surface 50b2 extends) are also rounded.

Note that both ends of the recess 50c1 provided in the first side surface 50a2 are located near the second side surfaces 50b1 and 50b2, respectively. Both ends of the recesses 50c2 provided in the second side surface 50b2 are located near the first side surfaces 50a1 and 50a2, respectively. That is, the separately provided recesses 50c1 and 50c2 extend across substantially the entire first side surface 50a2 or the second side surface 50b2. The first side surface 50a1 is also provided with a recess that is similar to the recess 50c1, and the second side surface 50b1 is also provided with a recess that is similar to the recess 50c2.

As a result, the same effect is obtained as with a configuration that uses the heat dissipating base plate 14 including the recess 14e provided continuously without interruption in the two first side surfaces 14b1 and 14b2 and the two second side surfaces 14c1 and 14c2 as depicted in FIG. 3.

Note that the outer shapes of both ends of the recesses 50c1 and 50c2 are rounded for the following reason.

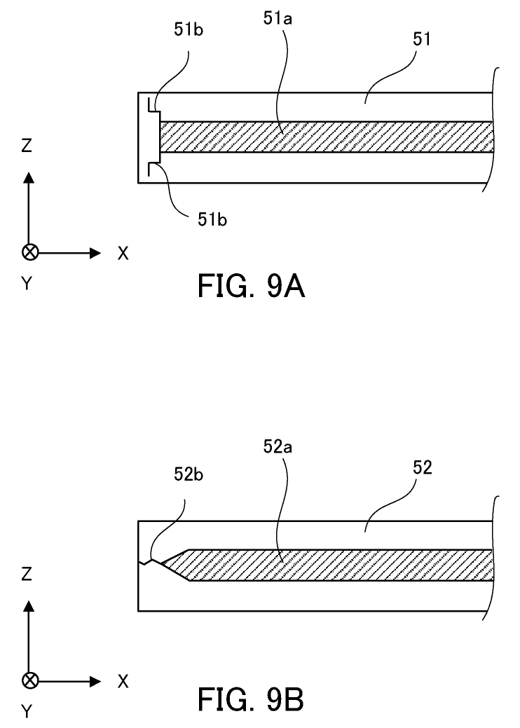

FIGS. 9A and 9B are diagrams depicting examples of cracks generated in cases where an end of a recess is rectangular or pointed with an acute angle in shape. FIG. 9A depicts part of a side surface of a heat dissipating base plate 51 provided with a recess 51a whose end is rectangular at a side surface. FIG. 9B depicts part of a side surface of a heat dissipating base plate 52 provided with a recess 52a whose end is pointed at an acute angle.

When an end is formed in a rectangular shape as with the recess 51a, stress becomes concentrated at the corners during the process of expansion and contraction, resulting in concern that cracks 51b that start from the corners may be produced and propagate. When this happens, there is the risk of problems such as a fall in strength, a fall in heat dissipation performance due to increases in an air layer that accompany propagation of the cracks 51b, and even unexpected local corrosion of the heat dissipating base plate 51 in high humidity environments.

In the same way, for a configuration where the end is pointed at an acute angle as with the recess 52a, stress will be concentrated at the point, resulting in a crack 52b that starts from the point being produced. This risks problems such as a fall in strength, a fall in heat dissipation performance, and local corrosion of the heat dissipating base plate 52.

For this reason, as depicted in FIG. 8, by rounding the outer shapes of both ends of the recesses 50c1 and 50c2, it is possible to eliminate locations where stress is concentrated, making it possible to prevent the problems described above from occurring.

From the viewpoint of eliminating locations where stress is concentrated, it is desirable for the bottoms of the recesses 50c1 and 50c2 to also be rounded in shape. It is also preferable for the bottom 14e1 of the recess 14e in the heat dissipating base plate 14 depicted in FIGS. 1A and 1B and the like to be formed in a rounded shape.

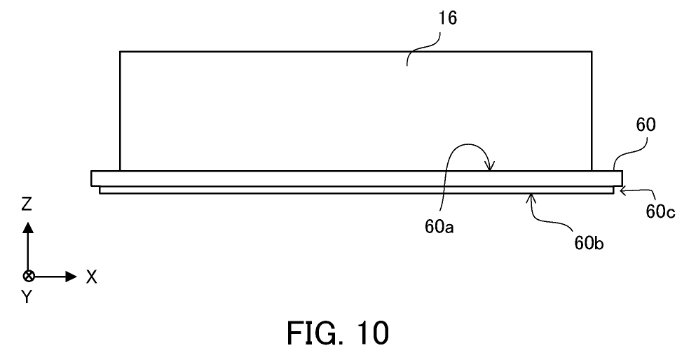

FIG. 10 depicts a modification to the formation position of the recess.

As depicted in FIGS. 1B and 2, the recess 14e of the heat dissipating base plate 14 is positioned between the upper surface 14a and the lower surface 14d of the heat dissipating base plate 14 and is provided near the center in the height direction of the first side surfaces 14b1 and 14b2 and the second side surfaces 14c1 and 14c2. However, the present disclosure is not limited to this configuration.

For a heat dissipating base plate 60 depicted in FIG. 10, a recess 60c is formed in each side surface of the heat dissipating base plate 60 by press machining the lower surface 60b-side to make it more recessed than the upper surface 60a-side. When the heat dissipating base plate 60 with this configuration is used, it is possible to obtain the same effects as when the heat dissipating base plate 14 is used.

### Manufacturing Method of Semiconductor Device

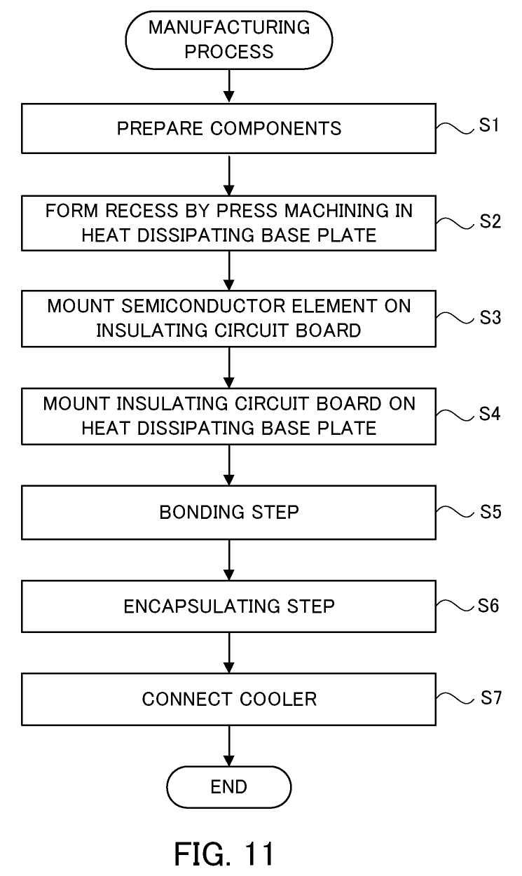

FIG. 11 is a diagram illustrating the flow of one example of a manufacturing process of a semiconductor device.

Step S1: A step of preparing components of the semiconductor device 10 is performed. The components include the insulating circuit board 11, the semiconductor elements 12a to 12c, the heat dissipating base plate 14, and external terminals and control terminals (not illustrated). The components may also include the cooler 21.

Step S2: A step of forming the recess 14e with the bottom 14e1 inside the heat dissipating base plate 14 in the two first side surfaces 14b1 and 14b2 and the two second side surfaces 14c1 and 14c2 of the heat dissipating base plate 14 by press machining is performed. Note that in this step S2, the recesses 50c1, 50c2, and 60c of the heat dissipating base plates 50 and 60 according to the modifications depicted in FIGS. 8 and 10 may be formed by press machining.

Step S3: A step of mounting the semiconductor elements 12a to 12c on the insulating circuit board 11 is performed. The semiconductor elements 12a to 12c are mounted via bonding materials 13a to 13c that have been disposed on the front surface (upper surface) of the metal plate 11b of the insulating circuit board 11. Note that bonding itself does not need to be performed in step S3.

Step S4: A step of mounting the insulating circuit board 11 on the heat dissipating base plate 14 is performed. The insulating circuit board 11 is mounted on the bonding material 15 disposed on the upper surface 14a of the heat dissipating base plate 14 so that the rear surface of the insulating circuit board 11 contacts the bonding material 15. Note that step S4 may be performed between step S2 and step S3.

Step S5: External terminals (as examples, positive terminals, negative terminals, or output terminals), control terminals, connection members (such as a lead frame) for electrically connecting the external terminals and the control terminals to the main electrodes and the control electrodes on the front surfaces of the semiconductor elements 12a to 12c, and bonding material are arranged, and a bonding step is then performed. When solder is used as the bonding material, the bonding step is performed under predetermined reflow conditions. When sintered material (copper or silver) is used as the bonding material, the bonding step is performed under predetermined sintering conditions.

Step S6: An encapsulating step is performed. In the encapsulating step, the insulating circuit board 11, the semiconductor elements 12a to 12c, and parts of the external terminals and the control terminals are encapsulated using the housing 16 in a state where ends of the external terminals and the control terminals are exposed. Through the steps described above, the semiconductor device 10 depicted in FIGS. 1A, 1B, and 2 is manufactured.

Step S7: A step of connecting the cooler 21 is performed. In this connecting step, as depicted in FIGS. 5A and 5B, the liquid compound 20 is applied to the lower surface 14d of the heat dissipating base plate 14, and the cooler 21 is connected via the liquid compound 20. The cooler 21 is fixed to the heat dissipating base plate 14 by fastening screws 22a to 22d inserted into through-holes 14f1 to 14f4 provided in the heat dissipating base plate 14.

Note that when the semiconductor device 10 is shipped in the state depicted in FIGS. 1A, 1B, and 2, step S7 may be omitted.

The semiconductor device 10 manufactured by the steps described above includes the heat dissipating base plate 14 with the recess 14e. As depicted in FIG. 4, the edge portion of the heat dissipating base plate 14 including the recess 14e is a high-density region 14g1 with higher density than the other region 14g2 of the heat dissipating base plate 14, has higher bending rigidity than the region 14g2, and is a rigid region. This means that the bending rigidity of the heat dissipating base plate 14 of the semiconductor device 10 is improved as a whole compared to the heat dissipating base plate 30. Since the bending rigidity is improved, warping-type behavior is suppressed and the amount of warping deformation is reduced, which reduces the pressing out of the liquid compound 20. As a result, it is possible to solve the problem of thermal breakdown occurring as described above.

Although one aspect of a semiconductor device and of a method of manufacturing the same according to the present disclosure have been described above based on the embodiment, these are mere examples. The present disclosure is not limited to the description given above.

According to one aspect, it is possible to improve the bending rigidity of a heat dissipating base plate of a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulating circuit board having a front surface and a rear surface;
a semiconductor element mounted on the front surface of the insulating circuit board; and
a heat dissipating base plate that is rectangular in shape, and that has:
an upper surface to which the rear surface of the insulating circuit board is bonded,
a lower surface that is opposite the upper surface,
two first side surfaces that are opposite to each other, and each extend in a first direction, and
two second side surfaces that are opposite to each other, and each extend in a second direction perpendicular to the first direction,
wherein the heat dissipating base plate has four recesses formed respectively in the two first side surfaces and the two second side surfaces.

2. The semiconductor device according to claim 1, further comprising a cooler that is connected via a liquid compound to the lower surface of the heat dissipating base plate.

3. The semiconductor device according to claim 1, wherein the heat dissipating base plate includes, at an edge portion thereof, a high-density region having a density higher than a region of the heat dissipating base plate aside from the edge portion, the recesses being in the edge portion.

4. The semiconductor device according to claim 1, wherein the four recesses are connected to be continuously provided without interruption in the two first side surfaces and the two second side surfaces.

5. The semiconductor device according to claim 1,
wherein the heat dissipating base plate includes a through-hole passing therethrough at each of four corners thereof in a plan view of the semiconductor device, and
in the plan view of the semiconductor device, the four recesses are located further outside than the four through-holes.

6. The semiconductor device according to claim 1, wherein the four recesses are separate from one another, and both ends of each of the recesses in the first direction or the second direction are rounded.

7. The semiconductor device according to claim 1, wherein the recesses are provided between the upper surface and the lower surface of the heat dissipating base plate.

8. A method of manufacturing a semiconductor device, the semiconductor device including:
an insulating circuit having a front surface and a rear surface;
a semiconductor element mounted on the front surface of the insulating circuit board; and
a heat dissipating base plate that is rectangular in shape, and that has:
an upper surface to which the rear surface of the insulating circuit board is bonded,
a lower surface that is opposite the upper surface,
two first side surfaces that are opposite to each other, and each extend in a first direction,
two second side surfaces that are opposite to each other, and each extend in a second direction perpendicular to the first direction, and
four recesses respectively provided in the two first side surfaces and the two second side surfaces,
the method comprising:
forming the recesses in the two first side surfaces and the two second side surfaces by a press machining.

9. The method of manufacturing a semiconductor device according to claim 8,
further comprising connecting a cooler via a liquid compound to the lower surface of the heat dissipating base plate.

10. The method of manufacturing a semiconductor device according to claim 8,
wherein the forming of the recesses by the press machining includes forming a high-density region, at an edge portion of the heat dissipating base plate including the recesses, the high-density region having a density higher than a region of the heat dissipating base plate aside from the edge portion.

11. The method of manufacturing a semiconductor device according to claim 8,
wherein the four recesses are connected continuously without interruption in the two first side surfaces and the two second side surfaces.

12. The method of manufacturing a semiconductor device according to claim 8,
further comprising forming, in the heat dissipating base plate, a through-hole passing therethrough at each of four corners thereof in a plan view of the semiconductor device,
wherein in the plan view of the semiconductor device, the four recesses are located further outside than the four through-holes.

13. The method of manufacturing a semiconductor device according to claim 8,
wherein the four recesses are separate from one another, and both ends of each of the recesses in the first direction or the second direction are rounded.
